(19) United States
(12) Patent Application Publication
(10) Pub. No.: US 2007/0109756 A1
(43) Pub. Date: May 17, 2007

(54) STACKED INTEGRATED CIRCUITS PACKAGE SYSTEM

(75) Inventors: Seung Wook Park, Singapore (KR); Soon Heung Bae, Singapore (KR)

Correspondence Address: ISHIMARU & ZAHRT LLP, 333 W. EL CAMINO REAL, SUITE 330, SUNNYVALE, CA, 94087, US

(73) Assignee: STATS CHIPPAC LTD., Singapore (SG)

(21) Appl. No.: 11/307,498

(22) Filed: Feb. 9, 2006

Related U.S. Application Data
(60) Provisional application No. 60/652,345, filed on Feb. 10, 2005.

(51) Int. Cl. H05K 7/00

(52) U.S. Cl. 361/760

(57) ABSTRACT

A stacked integrated circuits package system is provided providing a first substrate, mounting a first integrated circuit having a recess to the first substrate, and mounting a second integrated circuit in the recess.

### CROSS-REFERENCE TO RELATED APPLICATION(S)

This application claims the benefit of U.S. Provisional Patent Application Ser. No. 60/652,345 filed Feb. 10, 2005, and the subject matter thereof is hereby incorporated herein by reference thereto.

### TECHNICAL FIELD

The present invention relates generally to integrated circuit package and more particularly to the stacking integrated circuits package utilizing localized thinning.

### BACKGROUND ART

Modern consumer electronics, such as cellular phones, digital cameras, and music players, require shrinking integrated circuits and packing more integrated circuits into an ever shrinking physical space. Numerous technologies have been developed to meet these requirements. One of these technologies involves stacking the integrated circuits that are as thin as possible.

Wafer level thinning performs thinning on the inactive or backside of the wafer through processes such as lapping, grinding, back-lapping. However, the demands for large volume of integrated circuits push wafer fabrication to increase diameters that exacerbating wafer warpage or bowing. The wafer warpage leads to uneven thinning and breakage not only during wafer level thinning but also throughout manufacturing handling.

Thus, a need still remains for thinning the integrated circuits for more compact stacking structures beyond the wafer level thinning capabilities. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides providing a first substrate, mounting a first integrated circuit having a recess to the first substrate, and mounting a second integrated circuit in the recess.

Certain embodiments of the invention have other advantages in addition to or in place of those mentioned or obvious from the above. The advantages will become apparent to those skilled in the art from a reading of the following detailed description when taken with reference to the accompanying drawings.

### BRIEF DESCRIPTION OF THE DRAWINGS

FIG. 1 is a cross-sectional view of a stacked integrated circuits package system without the top encapsulant in an embodiment of the present invention;

FIG. 2 is a top view of the stacked integrated circuits package system without the top encapsulant in an embodiment of the present invention;

FIG. 3 is a cross-sectional view of a stacked integrated circuits package system without the top encapsulant in an alternative embodiment of the present invention;

FIG. 4 is a top view of the stacked integrated circuits package system without the top encapsulant in an alternative embodiment of the present invention;

FIG. 5 is a cross-sectional view of a stacked integrated circuits package system without the top encapsulant in yet another alternative embodiment of the present invention;

FIG. 6 is a top view of the stacked integrated circuits package system without the top encapsulant in yet another alternative embodiment of the present invention;

FIG. 7 is a cross-sectional view of the stacked integrated circuits package system of FIG. 1 in a die attach phase;

FIG. 8 is a cross-sectional view of the stacked integrated circuits package system of FIG. 1 in a localized thinning phase, after the die attach phase;

FIG. 9 is a cross-sectional view of the stacked integrated circuits package system of FIG. 1 in a stacking phase, after the localized thinning phase;

FIG. 10 is a cross-sectional view of the stacked integrated circuits package system of FIG. 1 in an alternative localized thinning phase;

FIG. 11 is a cross-sectional view of the stacked integrated circuits package system of FIG. 1 in an alternative die attach phase, after the alternative localized thinning phase;

FIG. 12 is a cross-sectional view of the stacked integrated circuits package system of FIG. 1 in an alternative stacking phase, after the alternative die attach phase; and

FIG. 13 is a flow chart of a system for a stacked integrated circuits package in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. Generally, the device can be operated in any orientation. The same numbers are used in all the figures to relate to the same elements.

The term “horizontal” as used herein is defined as a plane parallel to the conventional wafer surface, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “processing” as used herein includes deposition of material, patterning, exposure, development, etching, cleaning, molding, and/or removal of the material or as required in forming a described structure.

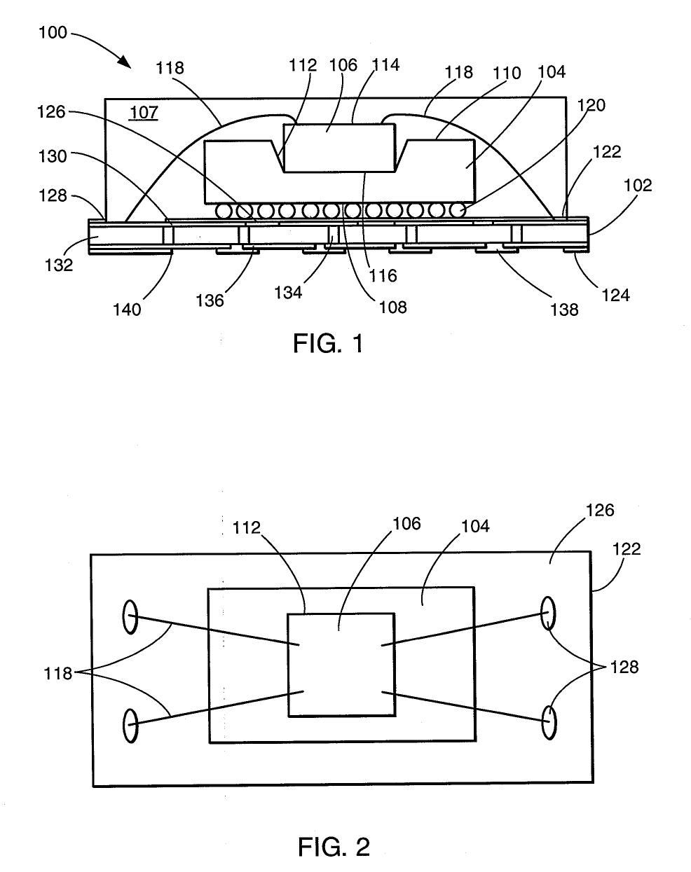

Referring now to FIG. 1, therein is shown a cross-sectional view of a stacked integrated circuits package system 100 without the top encapsulant in an embodiment of the present invention. The stacked integrated circuits package system 100 includes a first substrate 102, a first integrated circuit 104, and a second integrated circuit 106. The first integrated circuit 104 includes a first active side 108 with circuits fabricated thereon and a first back side 110.

The first back side 110 includes a recess 112 allowing the second integrated circuit 106 to be stacked on the first integrated circuit 104. The recess 112 may be formed from a number of processes such as engraving, chemical etching, laser etching, and reactive ion etch (RIE), wherein these processes locally thins the wafer or integrated circuit. For illustrative purposes, the second integrated circuit 106 is shown partially nested in the recess 112, although it is understood the second integrated circuit 106 may be completed nested in the recess 112, as well.

The second integrated circuit 106 includes a second active side 114 with circuits fabricated thereon and a second back side 116. The second back side 116 attaches to the recess 112. The second active side 114 electrically connects to the first substrate 102, wherein the electrical connection may be a number of connectivity structures such as wire bonds 118.

First electrical interconnect structures 120, such as solder bumps or stud bumps, attach to the first active side 108, wherein the first electrical interconnect structures 120 attach to the first substrate 102. The first substrate 102 includes a first surface 122 having the first integrated circuit 104 and the second integrated circuit 106 electrically connected thereto, and a second surface 124 having external electrical interconnect structures (not shown).

The first surface 122 also includes first insulating regions 126 with openings exposing first contact sites 128, wherein the first insulating regions 126 provide electrical isolation except for the first contact sites 128. The first contact sites 128 provide electrical connection sites to the first integrated circuit 104 and the second integrated circuit 106.

Between the first surface 122 and the second surface 124, the first substrate 102 also includes first metal regions 130 providing metal contacts for the first contact sites 128 and the first insulating regions 126 isolating the first metal regions 130 from one another. The first substrate 102 further includes a first insulating layer 132 surrounding vias 134 that electrically connect the first metal regions 130 to second metal regions 136. The first insulating layer 132 electrically isolates the vias 134 from one another, and also electrically isolates the first metal regions 130 from the second metal regions 136.

The second surface 124 includes second insulating regions 138 with openings exposing second contact sites 140 to the second metal regions 136, wherein the second insulating regions 138 provides electrical isolation except for the second contact sites 140. The second contact sites 140 provide electrical connection sites to the external electrical interconnect structures.

For illustrative purposes, the first substrate 102 is depicted as a two layer substrate, although it is understood the number of layers of the first substrate 102 may not be two. Also for illustrative purposes, the first contact sites 128 and the second contact sites 140 expose the first metal regions 130 and the second metal regions 136, respectively, although it is understood that different sites in the first contact sites 128 and the second contact sites 140 may expose different metal regions. Also for illustrative purposes, the recess 112 is depicted with the bottom horizontal dimension less than the top horizontal dimension, although it is understood that the bottom horizontal dimension and the top horizontal dimension may be the same or the bottom horizontal dimension may be greater than the top horizontal dimension, as well.

It is understood, the first insulating regions 126, first insulating layer 132, and the second insulating regions 138 include of electrically insulating material such as dielectric materials. The materials of the first insulating regions 126, first insulating layer 132, and the second insulating regions 138 may be similar or not.

Referring now to FIG. 2, therein is shown a top view of the stacked integrated circuits package system 100 without the top encapsulant in an embodiment of the present invention. The top view depicts the second integrated circuit 106 stacked above the first integrated circuit 104. The first integrated circuit 104 mounts on the first surface 122 shown. The first surface 122 includes the first insulating regions 126 with openings exposing the first contact sites 128, wherein the first contact sites 128 provide electrically connection sites to the second integrated circuit 106 with the wire bonds 118.

For illustrative purposes, the top view depicts the length and width of the recess 112 corresponding to the length and width of the second integrated circuit 106, although it is understood that the length and width of the recess 112 may be larger than to the length and width of the second integrated circuit 106. Also for illustrative purposes, the first insulating regions 126 is shown as a contiguous region, although it is understood that the first insulating regions 126 may not be contiguous and may comprise a number of different regions. It is also understood geometric shape of the first contact sites 128 may not be elliptical and may be another shape, such as a square, a rectangle, and a circle. The geometric shape of the recess 112 is outlined as a square, although it is understood that geometric shape may different, such as a circle or a rectangle, but must provide the length and width to fit the second integrated circuit 106.

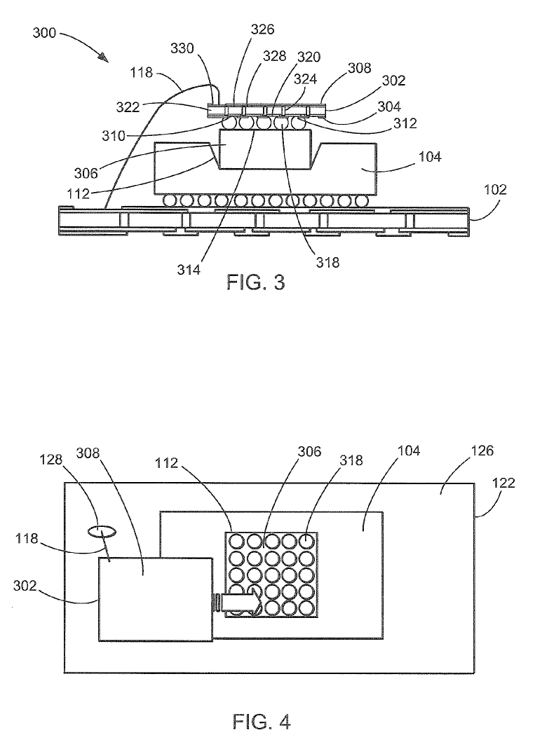

Referring now to FIG. 3, therein is shown a cross-sectional view of a stacked integrated circuits package system 300 without the top encapsulant in an alternative embodiment of the present invention. Similar to the stacked integrated circuits package system 100 of FIG. 1, the stacked integrated circuits package system 300 includes the first substrate 102 with a first integrated circuit 104 thereon and a second integrated circuit 306 in the recess 112.

Similar to the structure of the first substrate 102, a second substrate 302 includes a third surface 304 having the second integrated circuit 306 electrically connected thereto and a fourth surface 308. The third surface 304 also includes third insulating regions 310 with openings exposing third contact sites 312 wherein the third insulating regions 310 provides electrical isolation except for the third contact sites 312. The third contact sites 312 provide electrical connection sites to the second integrated circuit 306.

The second integrated circuit 306 has second electrical interconnect structures 318, such as solder bumps, and the second substrate 302. The second electrical interconnect structures 318 attach to a second active side 314 of the second integrated circuit 306. The second substrate 302 mounts on the second electrical interconnect structures 318. The fourth surface 308 of the second substrate 302 electrically connects to the first surface 122 of the first substrate 102 by the wire bonds 118.

The second substrate 302 includes third metal regions 320 providing metal contacts for the third contact sites 312 and the third insulating regions 310 isolating the third metal regions 320 from each other. Between the third surface 304 and the fourth surface 308, the second substrate 302 further includes a second insulating layer 322 surrounding vias 324 that electrically connect the third metal regions 320 to fourth metal regions 326. The second insulating layer 322 electrically isolates the vias 324 from one another and the third metal regions 320 from the fourth metal regions 326.

The fourth surface 308 includes fourth insulating regions 328 with openings exposing fourth contact sites 330 to the fourth metal regions 326, wherein the fourth insulating regions 328 provides electrical isolation except for the fourth contact sites 330. The fourth contact sites 330 provide electrical connection sites to the first substrate 102 and the second substrate 302 with the wire bonds 118.

For illustrative purposes, the second substrate 302 is depicted as a two layer substrate, although it is understood the number of layers of the second substrate 302 may not be two. Also for illustrative purposes, the third contact sites 312 and the fourth contact sites 330 expose the third metal regions 320 and the fourth metal regions 326, respectively, although it is understood that different sites in the third contact sites 312 and the fourth contact sites 330 may expose different metal regions. Also for illustrative purposes, the horizontal dimension of the second substrate 302 is shown to not to fit in the recess 112, although it is understood that it may depending if the second integrated circuit 306 partially or completely fits into the recess 112. Also for illustrative purposes, the recess 112 is depicted with the bottom horizontal dimension less than the top horizontal dimension, although it is understood that the bottom horizontal dimension and the top horizontal dimension may be the same or the bottom horizontal dimension may be greater than the top horizontal dimension, as well.

It is understood, the third insulating regions 310, the second insulating layer 322, and the fourth insulating regions 328 comprise of electrically insulating material such as dielectric materials. The materials of the third insulating regions 310, the second insulating layer 322, and the fourth insulating regions 328 may be similar or not.

Referring now to FIG. 4, therein is shown a top view of the stacked integrated circuits package system 300 without the top encapsulant in an alternative embodiment of the present invention. Similar to the top view of FIG. 2, this top view depicts the second integrated circuit 106 stacked above the first integrated circuit 104. The first integrated circuit 104 mounts on the first surface 122 shown. The first surface 122 includes the first insulating regions 126 and the first contact sites 128.

The second electrical interconnect structures 318 are on the second integrated circuit 306 and the second substrate 302. The wire bonds 118 electrically connect the first contact sites 128 to the second substrate 302. The second substrate 302 is shown prior to mounting above the second integrated circuit 306, although it is understood the stacked integrated circuits package system 300 has the second substrate 302 mounted on the second electrical interconnect structures 318. The fourth surface 308 is shown as a homogeneous surface although it is understood the fourth surface 308 includes the fourth contact sites 330 (not shown) of FIG. 3 and the fourth insulating regions 328 (not shown) of FIG. 3.

For illustrative purposes, the top view depicts the length and width of the recess 112 corresponding to the length and width of the second integrated circuit 306, although it is understood that the length and width of the recess 112 may be larger than the length and width of the second integrated circuit 306. The recess 112 is shown in the shape of a square, although it is understood that the shape may be different, but must provide the length and width to fit the second integrated circuit 306.

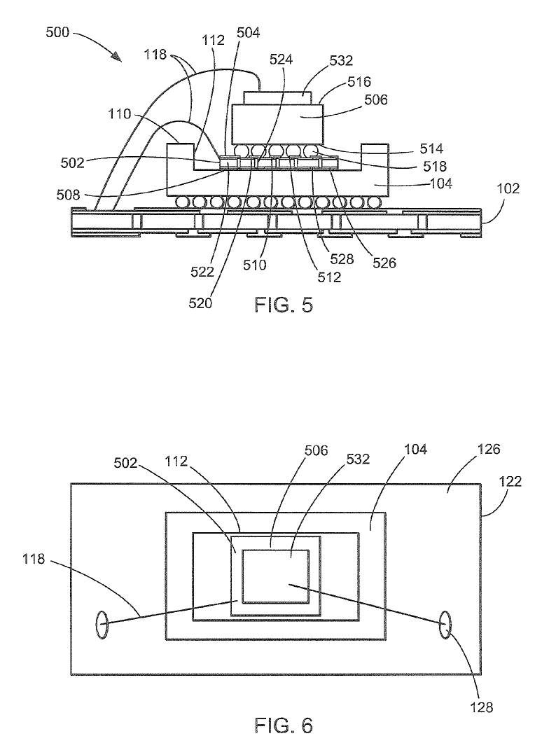

Referring now to FIG. 5, therein is shown a cross-sectional view of a stacked integrated circuits package system 500 without the top encapsulant in yet another alternative embodiment of the present invention. Similar to FIG. 1, the stacked integrated circuits package system 500 includes the first substrate 102 having the first integrated circuit 104 electrically connected thereto. The first back side 110 includes the recess 112 for the mounting a second integrated circuit 506.

Similar to FIG. 3, a second substrate 502 includes a third surface 504, wherein the third surface 504 having third contact sites 512 for electrical connection to second electrical interconnect structures 518, attached to a second active side 514. The second substrate 502 also includes third insulating regions 510, third metal regions 520, vias 524 connecting the third metal regions 520 to fourth metal regions 526 through a second insulating layer 522. Fourth insulating regions 528 electrically separate the fourth metal regions 526.

A third integrated circuit 532 is stacked on a second backside 516 of the second integrated circuit 506. The second substrate 502 along with the second integrated circuit 506 are vertically flipped from the orientation shown in FIG. 3. A fourth surface 508 attaches to the recess 112, wherein the fourth surface 508 having the fourth insulating regions 528 without openings for contact sites. The third contact sites 512 electrically connect to the first substrate 102 and the second substrate 502 by the wire bonds 118. The third integrated circuit 532 electrically connects to the first substrate 102 by the wire bonds 118.

For illustrative purposes, the second substrate 502 is depicted as a two layer substrate, although it is understood the number of layers of the second substrate 502 may not be two. Also for illustrative purposes, the third contact sites 512 expose the third metal regions 520 , although it is understood that different sites in the third contact sites 512 may expose different metal regions. Also for illustrative purposes, the bottom horizontal dimension and the top horizontal dimension of the recess 112 are the same, although it is understood that the bottom horizontal dimension and the top horizontal dimension of the recess 112 may differ.

It is understood, the third insulating regions 510, the second insulating layer 522, and the fourth insulating regions 528 comprise of electrically insulating material such as dielectric materials. The materials of the third insulating regions 510, the second insulating layer 522, and the fourth insulating regions 528 may be similar or not.

Referring now to FIG. 6, therein is shown a top view of the stacked integrated circuits package system 500 without the top encapsulant in yet another alternative embodiment of the present invention. Similar to the top view of FIG. 2, this top view depicts the second integrated circuit 106 stacked above the first integrated circuit 104. The first integrated circuit 104 mounts on the first surface 122 shown. The first surface 122 includes the first insulating regions 126 and the first contact sites 128.

The third integrated circuit 532 is mounted on the second integrated circuit 106, the second substrate 302 below the second integrated circuit 106, and the electrical connections of the first contact sites to the third integrated circuit 532 by the wire bonds 118. For illustrative purposes, the recess 112 is shown in the shape of a rectangle, although it is understood that the shape may be different, but must provide the length and width to fit the second integrated circuit 106 and the second substrate 302.

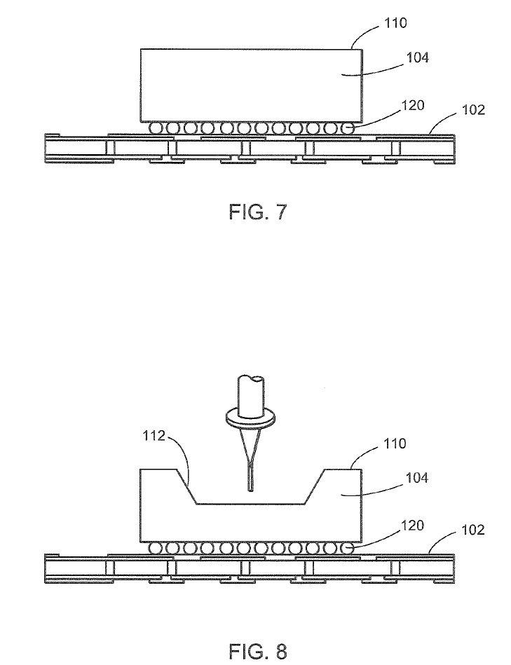

Referring now to FIG. 7, therein is shown a cross-sectional view of the stacked integrated circuits package system 100 of FIG. 1 in a die attach phase. During this phase, the wafer (not shown) with a number of instances of the first integrated circuit 104 undergoes a process, such as solder bumping, to attach the first electrical interconnect structures 120 to the first active side 108 of each of the instances of the first integrated circuit 104. Next, the wafer undergoes dicing to separate the number of instances of the first integrated circuit 104. After dicing, the first electrical interconnect structures 120 attaches to the first substrate 102. For illustrative purposes, the first integrated circuit 104 is shown as an integrated circuit after dicing, although it is understood that it may be part of a wafer before dicing. The first integrated circuit 104 may have previously undergone one or more thinning processes at the wafer level to ease subsequent localized thinning process.

Referring now to FIG. 8, therein is shown a cross-sectional view of the stacked integrated circuits package system 100 of FIG. 1 in a localized thinning phase, after the die attach phase. During this phase, the localized thinning process creates the recess 112 on the first back side 110 of the first integrated circuit 104 that is mounted on the first substrate 102. There are a number of processes for localized thinning such as engraving, chemical etching, laser etching, and RIE. The localized thinning process creates the slope of the walls, the horizontal dimensions, and the depth of the recess 112 required by the dimensions of the second integrated circuit 106 (not shown), the second substrate (if any, not shown), and the stacked integrated circuits package system 100 without cracking or fracturing the first integrated circuit 104. The localized thinning process may be an iterative process or a single step process to create the recess 112. During the localized thinning, a cleaning or vacuum system may be utilized to keep the site for the recess 112 free from unwanted abrasives that may cause fractures.

For illustrative purposes, the localized thinning process for creating the recess 112 is shown as localized and performed on the first integrated circuit 104, although it is understood that the localized thinning may also be performed at the wafer level prior to dicing or a combination thereof. A wafer level localized thinning system requires a wafer map of good integrated circuits along with the appropriate control system.

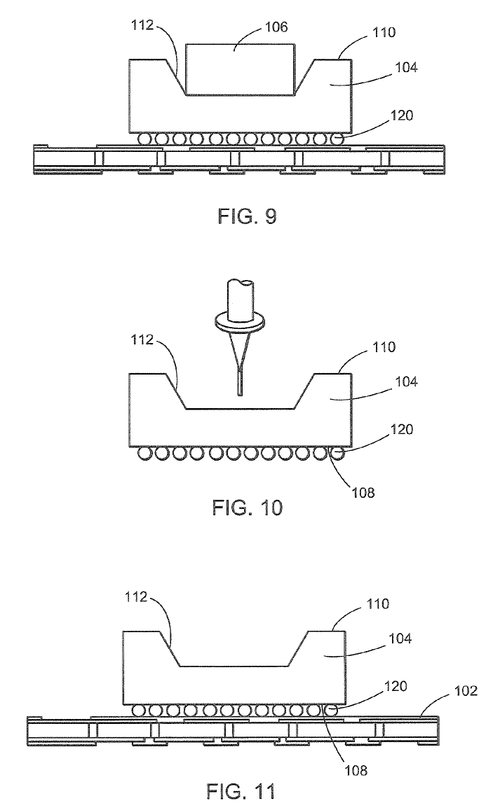

Referring now to FIG. 9, therein is shown a cross-sectional view of the stacked integrated circuits package system 100 of FIG. 1 in stacking phase, after the localized thinning phase. During this phase, the second integrated circuit 106 attaches to the first integrated circuit 104 inside the recess 112. The second integrated circuit 106 attachment may be provided by a number of processes, such as mechanical adhesive attach or mechanical and thermal attach.

It is understood that the vertical force to attach the second integrated circuit 106 on the first integrated circuit 104 ensures adhesion without causing cracks or fractures. The first substrate 102 and the first electrical interconnect structures 120 provides structure rigidity to withstand the attachment force to minimize warpage of the first integrated circuit 104.

Referring now to FIG. 10, therein is shown a cross-sectional view of the stacked integrated circuits package system 100 of FIG. 1 in an alternative localized thinning phase. During this phase, the wafer (not shown) with a number of instances of the first integrated circuit 104 undergoes a process, such as solder bumping, to attach the first electrical interconnect structures 120 to the first active side 108 of each instance of the first integrated circuit 104. Next, the wafer undergoes dicing to separate the instances of the first integrated circuit 104.

Similar to the localized thinning of FIG. 8, the alternative localized thinning phase creates the recess 112 on the first back side 110 of the first integrated circuit 104 for the dimensions required by the second integrated circuit 106 (not shown) of FIG. 1, the second substrate 302 of FIG. 5 (if any), and the stacked integrated circuits package system 100. There are a number of processes for localized thinning such as engraving, chemical etching, laser etching, and RIE. The localized thinning process may be an iterative process or a single step process to create the recess 112. During the localized thinning, a cleaning or vacuum system may be utilized to keep the site for the recess 112 free from unwanted abrasives that may cause fractures.

For illustrative purposes, the first integrated circuit 104 is shown as an integrated circuit after dicing, although it is understood that it may be a wafer before dicing. The first integrated circuit 104 may have previously undergone one or more thinning processes at the wafer level to ease subsequent localized thinning process. Also for illustrative purposes, the localized thinning process for creating the recess 112 is shown as localized and performed on the first integrated circuit 104, although it is understood that the localized thinning may also be performed at the wafer level prior to dicing or a combination thereof. A wafer level localized thinning system requires a wafer map of good integrated circuits.

Referring now to FIG. 11, therein is shown a cross-sectional view of the stacked integrated circuits package system 100 of FIG. 1 in an alternative die attach phase, after the alternative localized thinning phase. During this phase, the first integrated circuit 104 having the recess 112 on the first back side 110 and the first electrical interconnect structures 120 on the first active side 108 undergo die attachment with the first electrical interconnect structures 120 attached to the first substrate 102. Die attach after the localized thinning avoids impurities that results from localized thinning in this phase.

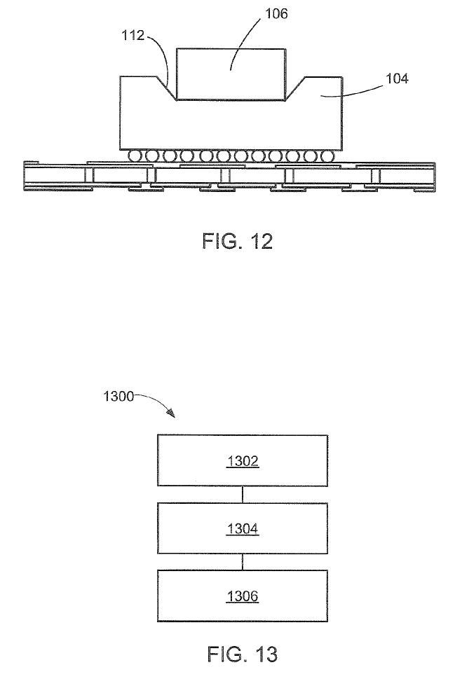

Referring now to FIG. 12, therein is shown a cross-sectional view of the stacked integrated circuits package system 100 of FIG. 1 in an alternative stacking phase, after the alternative die attach phase. Similar to the stacking phase of FIG. 9, this phase attaches the second integrated circuit 106 to the first integrated circuit 104 inside the recess 112. The second integrated circuit 106 attachment may be provided by a number of processes, such as mechanical adhesive attach or mechanical and thermal attach.

Referring now to FIG. 13, therein is shown a flow chart of a system 1300 for a stacked integrated circuits package in an embodiment of the present invention. The stacked integrated circuits package system 1300 includes providing a first substrate in a block 1302; mounting a first integrated circuit having a recess to the first substrate in a block 1304; and mounting a second integrated circuit in the recess in a block 1306.

It has been discovered that the present invention thus has numerous advantages.

It has been discovered that more compact integrated circuits stacks are possible when a localized thinning process is used to create recesses on the back side of integrated circuits to nest or receive additional integrated circuit. This stacking is possible because localized thinning occurs on integrated circuits after dicing, thus alleviating wafer warpage or bowing concerns that may cause uneven thinning and breakage. Wafer level thinning can still be employed to remove partial materials from the back side of the wafer without exposing the wafer to fractures. The localized thinning can create the recess in a fine-tuned fashion thereby also reducing the risk of fractures or breakage.

An aspect is that the present invention creates a highly compact integrated circuits stacking structure without risking wafer yields from aggressive wafer level thinning. Localized thinning applied to the entire back side of an integrated circuit die creates thinner integrated circuits beyond the capability of a wafer level thinning process. The positive impacts of this invention are attainable using existing manufacturing equipment and processes. Additional positive impacts of this invention are extensible to new and compact integration possibilities.

Another aspect of the present invention is that the recess may be used in a number of combinations to stack integrated circuits. Multiple recesses on a back side of an integrated circuit may be used to stack an integrated circuit in each recess. Alternating integrated circuits stacking layers with recess and those without may used to stack integrated circuits while providing additional flexibility for different stacking structures. Interlocking recesses from one stack level to the next increase the integrated circuit densities both horizontally and vertically. Any combination mentioned and other combinations are possible.

Yet another important aspect of the present invention is that it valuably supports and services the historical trend of reducing costs, simplifying systems, and increasing performance. These and other valuable aspects of the present invention consequently further the state of the technology to at least the next level.

Thus, it has been discovered that the stacked integrated circuits package system method of the present invention furnishes important and heretofore unknown and unavailable solutions, capabilities, and functional advantages for increasing chip density in systems while making the multiple device packages easier to manufacture reliably. The resulting processes and configurations are straightforward, cost-effective, uncomplicated, highly versatile and effective, can be implemented by adapting known technologies, and are thus readily suited for efficiently and economically manufacturing stacked integrated circuit packaged devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

1. A stacked integrated circuits package system comprising:
providing a first substrate;
mounting a first integrated circuit having a recess to the first substrate; and
mounting a second integrated circuit in the recess.

2. The system as claimed in claim 1 wherein mounting the first integrated circuit having a recess to the first substrate comprises etching the recess on a back side of the first integrated circuit.

3. The system as claimed in claim 1 further comprising locally thinning a back side of the first integrated circuit.

4. The system as claimed in claim 1 further comprising:
attaching electrical interconnect structures on the second integrated circuit;
connecting a second substrate to the electrical interconnect structures on the second integrated circuit; and
electrically connecting the second substrate to the first substrate.

5. The system as claimed in claim 1 wherein mounting a second integrated circuit in the recess comprises:
mounting a second substrate in the recess;
forming electrical interconnect structures to the second integrated circuit;
connecting the electrical inteconnect structures on the second integrated circuit to the second substrate;
mounting a third integrated circuit on the second integrated circuit; and
electrically connecting the second substrate and the third integrated circuit to the first substrate.

6. A stacked integrated circuits package system comprising:
providing a first substrate;
providing a first integrated circuit having electrical interconnect structures on an active side;
mounting the first integrated circuit on the first substrate with the electrical interconnect structures;
etching a recess on the back side of the first integrated circuit;
attaching a second integrated circuit in the recess; and
electrically connecting the second integrated circuit to the first substrate.

7. The system as claimed in claim 6 further comprising encapsulating a mold compound over the first integrated circuit, the second integrated circuit, and the first substrate.

8. The system as claimed in claim 6 wherein electrically connecting the second integrated circuit comprises connecting wire bonds to electrically connect the second integrated circuit to the first substrate.

9. The system as claimed in claim 6 further comprising forming solder bumps on the first integrated circuit to electrically connect the first integrated circuit to the first substrate.

10. The system as claimed in claim 6 further comprising etching the back side of the first integrated circuit.

11. A stacked integrated circuits package system comprising:
a first substrate having a first integrated circuit mounted thereto;
a recess in the first integrated circuit; and
a second integrated circuit in the recess.

12. The system as claimed in claim 11 wherein the recess in the first integrated circuit comprises the recess on a back side of the first integrated circuit.

13. The system as claimed in claim 11 wherein the first integrated circuit having the recess includes the recess having different geometric shapes.

14. The system as claimed in claim 11 further comprising:
electrical interconnect structures on the second integrated circuit;
a second substrate connected to the electrical interconnect structures on the second integrated circuit; and
the second substrate electrically connected to the first substrate.

15. The system as claimed in claim 11 wherein the second integrated circuit in the recess comprises:
a second substrate in the recess;
electrical interconnect structures on the second integrated circuit, wherein the electrical interconnect structures electrically connected on the second substrate;
a third integrated circuit on the second integrate circuit; and
the second substrate and the third integrated circuit electrically connected to the first substrate.

16. A stacked integrated circuits package system comprising:
a first substrate;
a first integrated circuit having electrical interconnect structures on an active side, wherein the first integrated circuit mounted on the first substrate with the electrical interconnect structures;
a recess on the back side of the first integrated circuit;
a second integrated circuit in the recess, wherein the second integrated circuit electrically connected to the first substrate.

17. The system as claimed in claim 16 further comprising a mold compound over the first integrated circuit, the second integrated circuit, and the first substrate.

18. The system as claimed in claim 16 further comprising wire bonds to electrically connect the second integrated circuit to the first substrate.

19. The system as claimed in claim 16 further comprising solder bumps on the first integrated circuit to electrically connect the first integrated circuit to the first substrate.

20. The system as claimed in claim 16 further comprising integrated circuits stacked above the second integrated circuit electrically connected to the first substrate.
